(19) United States
(12) Patent Application Publication
(10) Pub. No.: US 2024/0332829 A1
(43) Pub. Date: Oct. 3, 2024

(54) BUSBAR CONNECTION STRUCTURE

(71) Applicant: HONDA MOTOR CO., LTD., Tokyo (JP)

(72) Inventor: Takahiro HAGIMOTO, Saitama (JP)

(21) Appl. No.: 18/583,885

(22) Filed: Feb. 22, 2024

(30) Foreign Application Priority Data
Mar. 31, 2023 (JP) 2023-057853

(51) Int. Cl. H01R 4/70; H01R 4/30; H01R 4/34

(52) U.S. Cl. CPC H01R 4/70; H01R 4/302; H01R 4/304; H01R 4/34

(57) ABSTRACT

The objective is to improve the electrical conductivity and heat conductivity at the connection part of the busbars while suppressing the loosening of bolts. The busbar connection structure includes a terminal block body, a fastening part, a fastened base, a bolt, grease, and a thread locking member. The fastening part fastens the terminal block body to the cooling section. The fastened base is attached to the terminal block body and includes a thread hole. The bolt fastens the connection part of the busbars to the fastened base. The grease is electrically conductive and is applied at the connection part of the busbars. The thread locking member is interposed between the outer circumferential surface of the bolt and the inner circumferential surface of the thread hole, and suppresses the loosening of the bolt by biting into the outer and inner circumferential surfaces.

This application is based on and claims the benefit of priority from Japanese Patent Application No. 2023-057853, filed on 31 Mar. 2023, the content of which is incorporated herein by reference.

### BACKGROUND OF THE INVENTION

### Field of the Invention

The present invention relates to a busbar connection structure for electrically connecting busbars.

### Related Art

Some busbar connection structures allow a connection part of a plurality of busbars to be physically connected while being electrically insulated from a cooling section, thereby enabling heat transfer.
Patent Document 1: Japanese Patent No. 6623392

### SUMMARY OF THE INVENTION

The present inventors have considered using the following busbar connection structure. The busbar connection structure includes a terminal block and a heat transfer sheet. The terminal block includes a terminal block body, a fastened part, and a fastening part.

The terminal block body is an insulator. The fastening part fastens the terminal block body to the cooling section. A fastened base that is an electrical conductor is attached to the terminal block body and has a thread hole. A bolt is threaded into the thread hole in the state of being engaged with the connection part of the busbars, thereby fastening the connection part to the fastened base. The heat transfer sheet is an insulator interposed between the fastened base and the cooling section. Thus, the connection part of the busbars is physically connected to the cooling section via the fastened base and the heat transfer sheet, thereby enabling heat transfer. The heat transfer sheet as an insulator electrically insulates the connection part of the busbars from the cooling section.

The inventors have focused on improving the electrical conductivity and heat conductivity between the busbars, and the heat conductivity between the busbar and the fastened base, at the connection part, to achieve a more preferable outcome.

However, applying grease to the parts fastened by bolts is avoided in general. The risk is that grease entering the thread holes may cause the bolts to loosen in the thread holes. Specifically, such loosening may occur under external disturbances such as vibrations. Consequently, applying grease to the connection part of the busbars in order to enhance the electrical conductivity and heat conductivity is typically impractical.

In light of the above situation, the present invention has been made with the objective of improving the electrical conductivity and heat conductivity at the connection part of the busbars while suppressing the loosening of the bolts in the thread holes.

The present inventors have found that the above objective can be achieved by applying electrically conductive grease to the connection part of the busbars and interposing a thread locking member between the outer circumferential surface of the bolt and the inner circumferential surface of the thread hole. The present invention is the busbar connection structure as described below in (1).

(1) A busbar connection structure that electrically connects busbars to each other and connects a connection part of the busbars to a cooling section in a way that allows heat transfer while being electrically insulated, in which the busbar connection structure includes:
a terminal block body as an insulator;
a fastening part that fastens the terminal block body to the cooling section;
a fastened base as an electrical conductor attached to the terminal block body so as to be exposed to outside of the terminal block body, the fastened part including a thread hole;
a heat transfer sheet as an insulator interposed between the fastened base and the cooling section;
a bolt that fastens the connection part to the fastened base by being threaded into the thread hole while engaging the connection part;
electrically conductive grease applied in an area of the connection part, the area including an area between the busbars and an area between the busbar and the fastened base; and
a thread locking member interposed between an outer circumferential surface of the bolt and an inner circumferential surface of the thread hole, the thread locking member suppressing loosening of the bolt in the thread hole by biting into the outer circumferential surface and the inner circumferential surface.

According to this configuration, the electrically conductive grease improves the electrical conductivity and heat conductivity between the busbars, as well as the heat conductivity between the busbar and the fastened base.

Moreover, the thread locking member suppresses loosening of the bolt in the thread hole due to external disturbances such as vibrations. Thus, this configuration can enhance the electrical conductivity and heat conductivity at the connection part of the busbars while suppressing loosening of the bolt in the thread hole.

### BRIEF DESCRIPTION OF THE DRAWINGS

FIG. 1 is a perspective view illustrating a busbar connection structure of a first embodiment;

FIG. 2 is an exploded perspective view illustrating the busbar connection structure;

FIG. 3 is a front sectional view illustrating the busbar connection structure;

FIG. 4 is a front sectional view illustrating a busbar connection structure of a first comparative example; and

FIG. 5 is a front sectional view illustrating a busbar connection structure of a second comparative example.

### DETAILED DESCRIPTION OF THE INVENTION

Hereinafter, embodiments of the present invention will be described with reference to the drawings. However, the present invention is not limited to the following embodiments and can be implemented with appropriate modifications within a scope that does not deviate from the spirit of the invention.

### First Embodiment

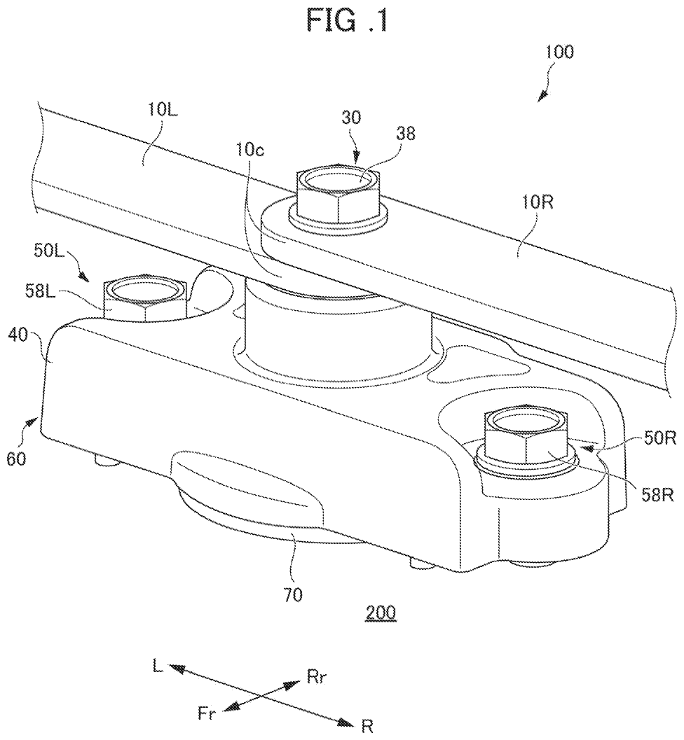

A busbar connection structure 100 as illustrated in FIG. 1 electrically connects busbars 10L, 10R, which transmit power, to each other, and also physically connects the connection part of the busbars 10L, 10R to a cooling section 200 to enable heat transfer, while electrically insulating them. The busbars 10L, 10R and the cooling section 200 are all made of an electrical conductor such as metal. The busbar connection structure 100 includes a terminal block 60 and a heat transfer sheet 70.

The terminal block 60 includes a terminal block body 40, a fastened part 30, and two fastening parts 50L, 50R. Hereinafter, the longitudinal direction of the terminal block 60 is referred to as the “left-right direction L, R”, a predetermined direction perpendicular to the left-right direction L, R is referred to as the “front-back direction Fr, Rr”, and the direction perpendicular to both the left-right direction L, R and the front-back direction Fr, Rr is referred to as the “up-down direction”. Therefore, for example, the aforementioned up-down direction is not limited to the vertical direction and may be a direction diagonal to the vertical direction or may be a horizontal direction.

The terminal block body 40 is made of an insulator such as resin and extends in the left-right direction L, R. The two fastening parts 50L, 50R fasten both ends of the terminal block 60 in the left-right direction L, R to the cooling section 200.

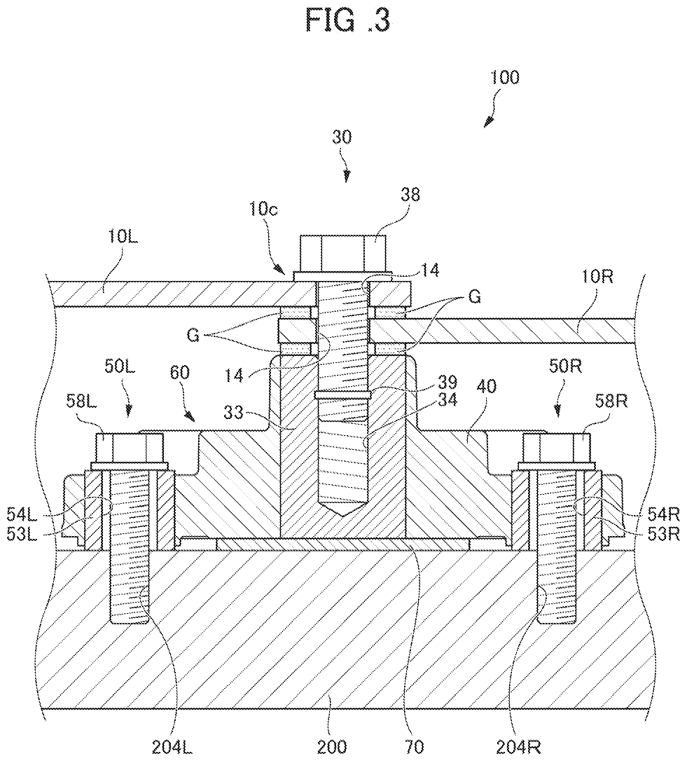

As illustrated in FIG. 3, the two fastening parts 50L, 50R include a left-side fastening part 50L and a right-side fastening part 50R. The left-side fastening part 50L includes a left-side fastening base 53L and a left-side bolt 58L. The right-side fastening part 50R includes a right-side fastening base 53R and a right-side bolt 58R.

Both the left and right fastening bases 53L, 53R are all made of an electrical conductor such as metal. The left-side fastening base 53L is attached to the left end of the terminal block body 40 and penetrates the left end in the up-down direction. Similarly, the right-side fastening base 53R is attached to the right end of the terminal block body 40 and penetrates the right end in the up-down direction. Thus, the upper and lower ends of the fastening bases 53L, 53R are exposed from the terminal block body 40. Each of the fastening bases 53L, 53R has a through-hole 54L, 54R that penetrates from the upper surface to the lower surface. Therefore, the left and right fastening bases 53L, 53R are cylindrical in shape and have through-holes 54L, 54R, respectively.

Fastening thread holes 204L, 204R are provided at the positions for attaching the left and right fastening bases 53L, 53R, respectively, in the cooling section 200. The left and right bolts 58L, 58R are all made of an electrical conductor such as metal. The left-side bolt 58L, passing through the through-hole 54L of the left-side fastening base 53L, is threaded into the thread hole 204L of the cooling section 200, and similarly, the right-side bolt 58R, passing through the through-hole 54R of the right-side fastening base 53R, is threaded into the thread hole 204R of the cooling section 200. As a result, the left and right fastening bases 53L, 53R are fastened to the cooling section 200, and the terminal block 60 is fastened to the cooling section 200.

As illustrated in FIG. 3, the fastened part 30 is located at the central part of the terminal block body 40 in the left-right direction L, R. The fastened part 30 includes a fastened base 33, a fastening bolt 38, a thread locking member 39, and grease G. Hereinafter, the fastening bolt 38 is simply referred to as “bolt 38”.

The fastened base 33 is an electrical conductor, such as a metal, attached to the central part of the terminal block body 40 in the left-right direction, and penetrates the central part in the up-down direction. Thus, the upper and lower ends of the fastened base 33 are exposed from the terminal block body 40. A thread hole 34, extending downward, is provided in the upper surface of the fastened base 33. Therefore, the fastened base 33 is cylindrical in shape and has the thread hole 34.

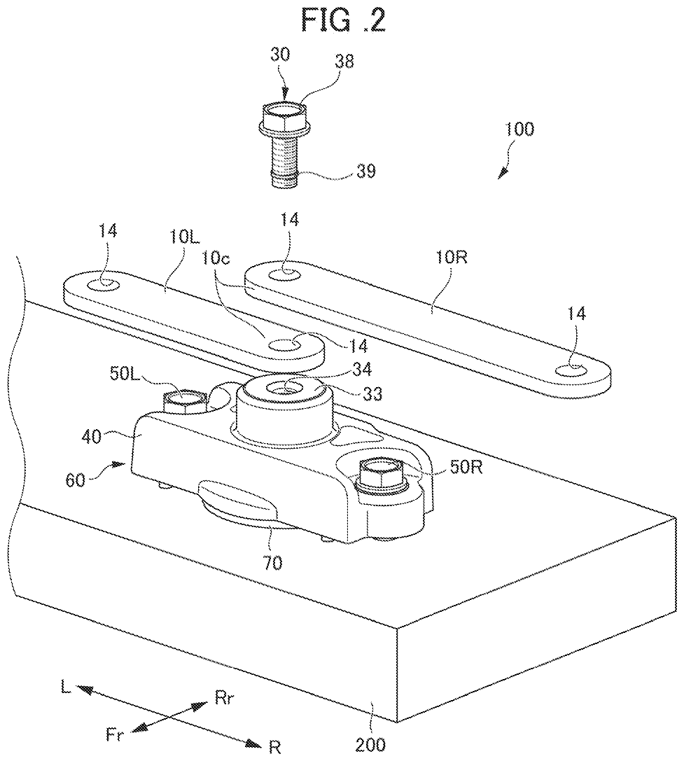

As illustrated in FIG. 2, the parts of the two busbars 10L, 10R to connect with each other are referred to as “busbar connection part 10c”. In the present embodiment, the busbar connection part 10c of the two busbars 10L, 10R, arranged in the left-right direction L, R, is fastened to the fastened part 30. Hereinafter, the left-side busbar of the two busbars 10L, 10R is referred to as “left-side busbar 10L”, and the right-side busbar as “right-side busbar 10R”. Alternatively, the two busbars fastened to the fastened part 30 may be arranged, for example, in the front-back direction Fr, Rr or in a diagonal direction relative to the front-back direction Fr, Rr and the left-right direction L, R.

Each of the busbars 10L, 10R has a through-hole 14 penetrating in the up-down direction at both left and right ends. Alternatively, instead of through-holes, notches penetrating in the up-down direction may be provided. As illustrated in FIG. 3, in the busbar connection part 10c, the ends of the two busbars 10L, 10R are overlapped in the up-down direction, so that the through-hole 14 of the left-side busbar 10L communicates with the through-hole 14 of the right-side busbar 10R.

Hereinafter, the state of passing through the through-hole 14 at the right end of the left-side busbar 10L and the through-hole 14 at the left end of the right-side busbar 10R is referred to as “the state of passing through the busbar connection part 10c”. Note that “the state of passing through” herein may also be referred to as “the state of being engaged”.

The bolt 38 is an electrical conductor such as a metal. The thread locking member 39 is a ring-shaped member made of resin or similar materials. The bolt 38 is threaded into the thread hole 34 with the thread locking member 39 fitted on the outside of the bolt 38 and in the state of passing through the busbar connection part 10c. As a result, the left and right-side busbars 10L, 10R are connected to each other and the busbar connection part 10c is fastened to the fastened base 33. The thread locking member 39 is interposed between the outer circumferential surface of the bolt 38 and the inner circumferential surface of the thread hole 34, and bites into the outer and inner circumferential surfaces, thereby suppressing the loosening of the bolt 38 in the thread hole 34.

The grease G is an electrically conductive grease. The grease G is applied in the area of the busbar connection part 10c including an area between the overlapping left and right-side busbars 10L, 10R, and an area between the lower busbar 10R and the fastened base 33. As a result, the grease G enhances the electrical conductivity and heat conductivity between the busbars 10L, 10R and improves the heat conductivity between the lower busbar 10R and the fastened base 33. Examples of the grease G include electrically conductive silicone grease, electrically conductive epoxy grease, liquid metal grease, etc.

The heat transfer sheet 70 is an insulator such as resin. When the terminal block 60 is attached to the cooling section 200, the heat transfer sheet 70 is sandwiched between the lower surface of the fastened base 33 and the upper surface of the cooling section 200. As a result, the heat transfer sheet 70 is interposed between the fastened base 33 and the cooling section 200. Thus, the busbar connection part 10c becomes physically connected to and capable of transferring heat to the cooling section 200 through the fastened base 33 and the heat transfer sheet 70. On the other hand, the busbar connection part 10c is electrically insulated from the cooling section 200 by the interposition of the heat transfer sheet 70.

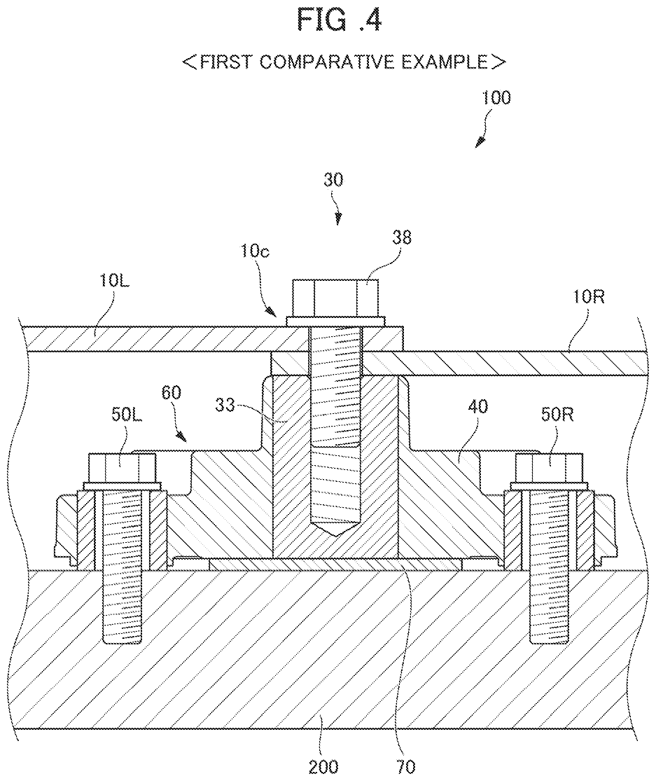

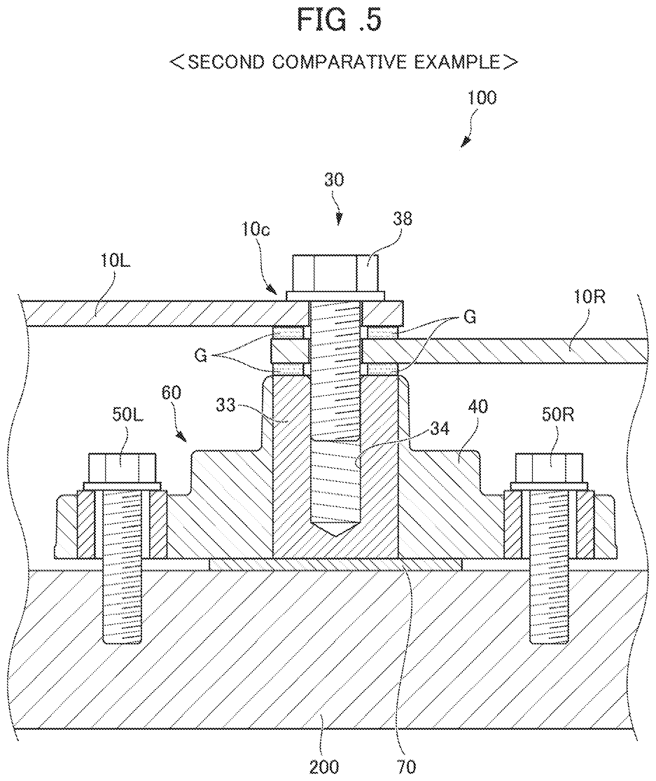

As illustrated in FIG. 4, an embodiment that removes both the grease G and the thread locking member 39 from the present embodiment is referred to as “first comparative example”. Additionally, as illustrated in FIG. 5, an embodiment that only removes the thread locking member 39 from the present embodiment is referred to as “second comparative example”.

The structure and effects of the present embodiment are summarized below, in comparison with these first and second comparative examples.

In the first comparative example illustrated in FIG. 4, there is a risk of clearance occurring due to dimensional errors or warping in part between the overlapping left and right-side busbars 10L, 10R at the busbar connection part 10c.

In such a case, the electrical conductivity and heat conductivity between the left and right-side busbars 10L, 10R will decrease. There is also a risk of clearance occurring due to dimensional errors or warping in part between the lower busbar 10R and the fastened base 33. In such a case, the heat conductivity between the lower busbar 10R and the fastened base 33 will decrease.

In contrast, in the present embodiment, as illustrated in FIG. 3, the electrically conductive grease G is applied between the left and right-side busbars 10L, 10R. Therefore, even if clearance occurs between the busbars 10L, 10R, the clearance will be filled with the electrically conductive grease G. This ensures sufficient electrical and physical connection between the busbars 10L, 10R, ensuring the electrical conductivity and heat conductivity therebetween.

Furthermore, the grease G is also applied between the lower busbar 10R and the fastened base 33. Thus, even if clearance occurs between the lower busbar 10R and the fastened base 33, the clearance will be filled with the grease G.

Therefore, sufficient physical connection between the lower busbar 10R and the fastened base 33 is ensured, and the heat conductivity therebetween is ensured. This ensures the heat conductivity from the left and right-side busbars 10L, 10R through the fastened base 33 to the cooling section 200.

As such, the grease G can improve the electrical conductivity and heat conductivity at the busbar connection part 10c.

However, in the second comparative example illustrated in FIG. 5, merely applying the grease G to the busbar connection part 10c may achieve the above effects, but there is a risk in that the grease G entering the thread hole 34 of the fastened base 33 might make the bolt 38 more prone to loosening in the thread hole 34. Specifically, the bolt 38 may be loosened under vibrations and other external disturbances.

In this respect, in the present embodiment as illustrated in FIG. 3, the thread locking member 39 is fitted on the outside of the bolt 38. The thread locking member 39 bites into the outer circumferential surface of the bolt 38 and the inner circumferential surface of the thread hole 34, thereby suppressing the loosening of the bolt 38 in the thread hole 34. Therefore, even when the grease G is applied, the thread locking member 39 can suppress the loosening of the bolt 38.

As such, the present embodiment can suppress the loosening of the bolt 38 in the thread hole 34 while improving the electrical conductivity and heat conductivity at the busbar connection part 10c.

### Other Embodiments

The embodiment described above can be modified in several ways such as the following. Instead of the two fastening parts 50L, 50R as illustrated in FIG. 3, the terminal block 60 may have only one fastening part or three or more fastening parts. Additionally, the terminal block 60 may have two or more of the fastened part 30 illustrated in FIG. 3.

### EXPLANATION OF REFERENCE NUMERALS

10L: left-side busbar
10R: right-side busbar
33: fastened base
34: thread hole
38: bolt
39: thread locking member
40: terminal block body
50L: left-side fastening part
50R: right-side fastening part
70: heat transfer sheet
100: busbar connection structure
200: cooling section
G: grease

What is claimed is:

1. A busbar connection structure that electrically connects busbars to each other and connects a connection part of the busbars to a cooling section in a way that allows heat transfer while being electrically insulated, the busbar connection structure comprising:
a terminal block body as an insulator;
a fastening part that fastens the terminal block body to the cooling section;
a fastened base as an electrical conductor attached to the terminal block body so as to be exposed to outside of the terminal block body, the fastened part including a thread hole;
a heat transfer sheet as an insulator interposed between the fastened base and the cooling section;
a bolt that fastens the connection part to the fastened base by being threaded into the thread hole while engaging the connection part;
electrically conductive grease applied in an area of the connection part, the area including an area between the busbars and an area between the busbar and the fastened base; and
a thread locking member interposed between an outer circumferential surface of the bolt and an inner circumferential surface of the thread hole, the thread locking member suppressing loosening of the bolt in the thread hole by biting into the outer circumferential surface and the inner circumferential surface.
